(19) United States
(12) Patent Application Publication
(10) Pub. No.: US 2009/0128375 A1
(43) Pub. Date: May 21, 2009

(54) Control Apparatus Having at Least One Pushbutton Switch and Domestic Appliance Having a Control Apparatus

(75) Inventors: Uwe Heimann, Wangen (DE); Klaus-Peter Koch, Weingarten (DE); Michael Prinz, Leutkirch (DE)

Correspondence Address: LERNER GREENBERG STEMER LLP, P O BOX 2480, HOLLYWOOD, FL, 33022-2480, US

(73) Assignee: DIEHL AKO STIFTUNG & CO. KG, Wangen (DE)

(21) Appl. No.: 12/265,307

(22) Filed: Nov. 5, 2008

(30) Foreign Application Priority Data
Nov. 16, 2007 (DE) 10 2007 054 778.3

(51) Int. Cl. H03K 17/94

(52) U.S. Cl. 341/34

(57) ABSTRACT

A control apparatus having at least one pushbutton switch can be used, for example, in a control panel of an electronic domestic appliance. The control apparatus includes a mount element, a piezo-film having at least one sensor field corresponding to the at least one pushbutton switch, a first adhesive layer connecting the piezo-film to the mount element, a cover layer facing a user side, a second adhesive layer connecting the cover layer to the piezo-film, and at least one attachment element for attachment of the control apparatus to the control panel. An electronic domestic appliance having a control apparatus is also provided.

### CROSS-REFERENCE TO RELATED APPLICATION

This application claims the priority, under 35 U.S.C. §119, of German Patent Application DE 10 2007 054 778.3, filed Nov. 16, 2007; the prior application is herewith incorporated by reference in its entirety.

### BACKGROUND OF THE INVENTION

1. Field of the Invention

The present invention relates to a control apparatus having at least one pushbutton switch, as may be used by way of example in a control panel for an electronic domestic appliance. The invention also relates to a domestic appliance having a control apparatus.

Pushbutton switches are known which use the piezo-effect. Pushbutton switches such as those contain a piezoelectric element which is disposed between two electrodes. When a pressure or a force is exerted on the piezoelectric element, a charge is released at the two electrodes, and that charge is proportional to the force exerted. Operation of the pushbutton switch can therefore be detected by measurement of that charge, with the necessary operating movement distance being very short.

The use of pushbutton switches such as those with a piezoelectric element has a number of advantages over conventional momentary-contact switches. Due to the minimal operating movement distances, there is no wear to mechanically moving parts, and the momentary-contact switch can be constructed to be simple and mechanically robust. Furthermore, no apertures, projections or depressions are required in the associated control panels, for example of the electronic domestic appliances, the pushbutton switch can therefore be disposed in such a way as to be moisture-proof, and the control panel can be cleaned easily.

It is known from the prior art for a so-called piezo-film, for example, to be used as a piezoelectric element for such a pushbutton switch. In the case of a piezo-film, a piezoelectric layer structure is produced, for example, by screen printing in a plurality of steps on a plastic film, with piezo-crystals being printed on, for example, in the form of a piezo-lacquer. The electrodes through which the electrical charge produced by the piezo-crystals is tapped off are disposed in that case between the layers of the multilayer structure, for example by printing.

In the case of electronic domestic appliances and the like, there is a requirement for a control apparatus which is very compact, is convenient to install and is also intended to have an integration level that is as high as possible.

### SUMMARY OF THE INVENTION

It is accordingly an object of the invention to provide a control apparatus having at least one pushbutton switch and a domestic appliance having a control apparatus, which overcome the hereinafore-mentioned disadvantages of the heretofore-known devices of this general type and in which the control apparatus has a very flat construction and is highly convenient to install.

With the foregoing and other objects in view there is provided, in accordance with the invention, a control apparatus with at least one pushbutton switch. The control apparatus comprises a mount element, a piezo-film having at least one sensor field corresponding to the at least one pushbutton switch, a first adhesive layer connecting the piezo-film to the mount element, a cover layer facing a user side,

a second adhesive layer connecting the cover layer to the piezo-film, and

at least one attachment element for attachment of the control apparatus to a control panel.

The construction of this control apparatus with a mount element, piezo-film and cover layer, represents a very flat structure. The control apparatus in this construction can be prefabricated and can thus be installed in a simple manner, as a unit, for example, in a control panel of an electronic domestic appliance. The control apparatus in this case preferably contains a multiplicity of pushbutton switches based on the piezo-effect.

In accordance with another feature of the invention, the mount element has a cutout on its side facing away from the piezo-film and the control apparatus also has a printed circuit board, which is inserted into the cutout in the mount element, and is preferably substantially completely held therein. This allows the control apparatus, including the printed circuit board, to have an extremely flat construction.

In accordance with another feature of the invention, the second adhesive layer between the piezo-film and the cover layer is soft and a force transmission element is disposed within an area cut out from the second adhesive layer between the piezo-film and the cover layer, in the area of the at least one sensor field, for example in the form of a plunger which is connected to the cover layer.

The transmission of the pressure applied by a finger at the cover layer of the control apparatus to the piezo-film actually requires a stiff and inflexible connection over an area between these two elements. However, since the materials which are used for these elements generally have different thermal coefficients of expansion, this can lead to temperature-dependent stressing and/or deformation, and in some circumstances even to damage, to the physical structure. If a soft and/or flexible connection over an area is used between the piezo-film and the cover layer, through the use of the second adhesive layer, it is possible to compensate for and/or to reduce the different thermal expansions of the components connected to one another. In order to allow the short operating movement distances to be transmitted from the cover layer to the piezo-film despite this soft connection over an area, a suitable force transmission element is provided between the two elements, and is disposed in a cutout in the second adhesive layer. Despite the soft connection over an area, this force transmission element produces the inflexible coupling between the cover layer and the sensor film, as is required for correct operation.

In accordance with a further feature of the invention, the at least one attachment element may contain a third adhesive layer and/or a latching apparatus.

In accordance with an added feature of the invention, the control apparatus also has at least one display element (light-emitting diode, display), which is likewise integrated in a compact and flat form in the mount element.

With the objects of the invention in view, there is concomitantly provided an electronic domestic appliance, comprising a control panel, and a control apparatus according to the invention inserted into the control panel. The control apparatus according to the invention as described above can be used in a particularly advantageous manner in a control panel for an electronic domestic appliance, although the invention is not intended to be restricted to this application.

Other features which are considered as characteristic for the invention are set forth in the appended claims.

Although the invention is illustrated and described herein as embodied in a control apparatus having at least one pushbutton switch and a domestic appliance having a control apparatus, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, perspective view of a control apparatus, inserted into a control panel, according to the invention;

FIG. 2 is an exploded, perspective view of a control apparatus according to a first exemplary embodiment;

FIG. 3 is an enlarged, longitudinal-sectional view of the control apparatus shown in FIG. 2, in an installed state;

FIG. 4 is a fragmentary, perspective view of the control apparatus shown in FIG. 2, in the installed state;

FIG. 5 is an exploded, perspective view of a control apparatus according to a second exemplary embodiment; and

FIG. 6 is an enlarged, longitudinal-sectional view of the control apparatus shown in FIG. 5.

### DETAILED DESCRIPTION OF THE INVENTION

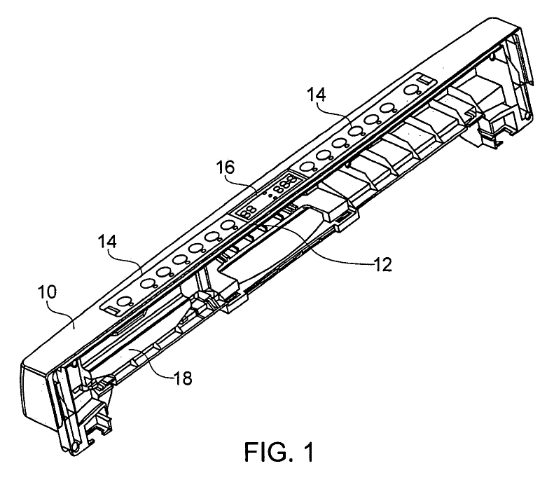

Referring now to the figures of the drawings in detail and first, particularly, to FIG. 1 thereof, there is seen, by way of example, a control panel 10 for an electronic domestic appliance (for example a cooker, a stove, a range, an oven, a cook top, a washing machine, a dryer, a dishwasher, etc.), although the invention is not intended to be restricted to this application.

The control panel 10 has a cutout on a side facing a user, which is at the top in FIG. 1, and into which a control apparatus (or control and display apparatus, or input/output apparatus) 12 is inserted. The control apparatus 12 has two input areas 14 each having a plurality of pushbutton switches and a central display area 16. An electronic controller 18 for the domestic appliance can also be seen in FIG. 1, and is connected to the control apparatus 12 through an appropriate non-illustrated connecting cable.

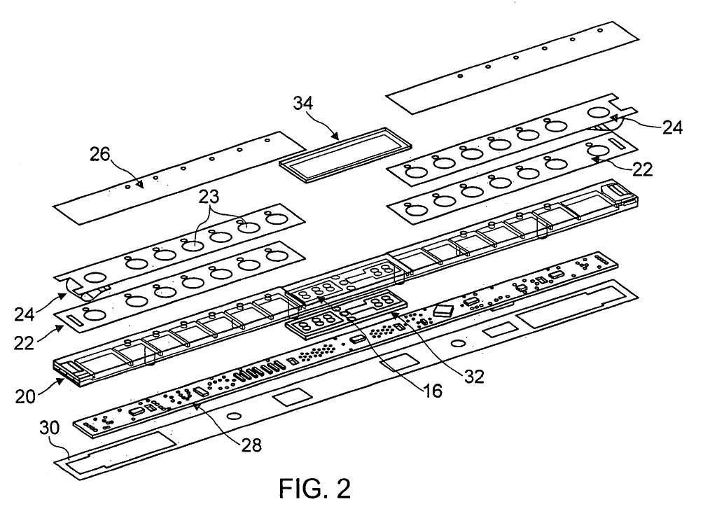

A first exemplary embodiment of a control apparatus 12 according to the invention will now be described in more detail with reference to FIGS. 2 to 4.

The control apparatus 12 contains a mount element 20 which is composed, for example, of plastic (for example PMMA) and has dimensions which substantially govern the size of the control apparatus 12. Two piezo-films 24 are disposed in the two input areas 14 of the control apparatus 12, on a side (at the top in FIG. 2) of the mount element 20 facing the user. The piezo-films 24 are connected to the mount element 20 through a first adhesive layer 22. The first adhesive layer 22 normally forms a flexible and soft connection over an area between the mount element 20 and the piezo-films 24.

In principle, any desired piezo-films may be used as the piezo-films 24 and the invention is not restricted to any specific type. The piezo-films 24 each include a multilayer piezoelectric element, which produces a voltage that can be measured at the electrodes as already explained in the introductory part of the description, when a pressure or a force is exerted. The piezo-films 24 each have a plurality of sensor fields 23, the number and configuration of which corresponds to the desired pushbutton switches for the control apparatus 12.

Two cover layers 26 are provided on the side (at the top in FIG. 1) of the piezo-films 24 facing the user and are each connected stiffly and inflexibly to the piezo-films 24 through a second adhesive layer which is not illustrated in FIG. 2. The cover layers 26 are in the form of a film, composed of metal, for example, and are used on one hand as an operating surface to which the user can apply pressure in order to operate a corresponding pushbutton switch at the position of a sensor field 23 on the piezo-film 24. These cover layers 26 identify the individual pushbutton switches for the user on the basis of the positions of the sensor fields 23 on the piezo-films 24, and finally act as a structural element for the control panel 10.

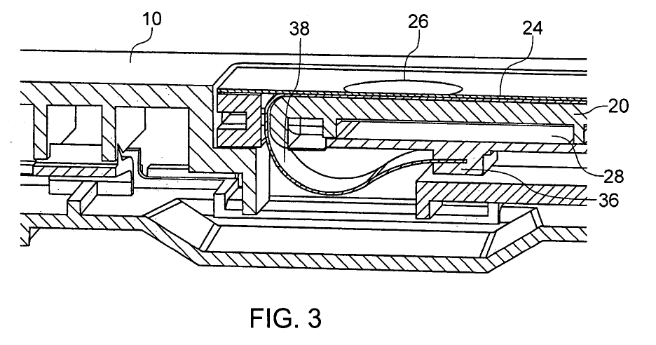

Furthermore, the control apparatus 12 has a printed circuit board 28 with evaluation and control electronics for the control apparatus. The electronics are inserted, and/or are preferably held substantially completely, in a cutout on a side (at the bottom in FIG. 2) of the mount element 20 facing away from the user. The printed circuit board 28 is normally firmly clamped in the corresponding recess in the mount element 20, or is optionally also fixed by adhesive points. As is illustrated in FIG. 3, the piezo-films 24 are each connected through a connecting cable 38 to a corresponding connection/plug 36 on a lower face of the printed circuit. The printed circuit board 28 is in turn connected through an appropriate connecting cable to the electronic controller 18, although this is not illustrated in the figures.

The layer structure of the control apparatus as described above, including the piezo-films 24 and the printed circuit board 28, results in a control apparatus having an extremely flat construction and a high degree of integration. The control apparatus 12 has a multiplicity of pushbutton switches, can be installed in advance as a unit, and can then be inserted into the control panel 10, thus considerably simplifying the installation of the pushbutton switches. Furthermore, at the same time, the control apparatus 12 carries out a structural function, if the cover layers 26 are appropriately constructed.

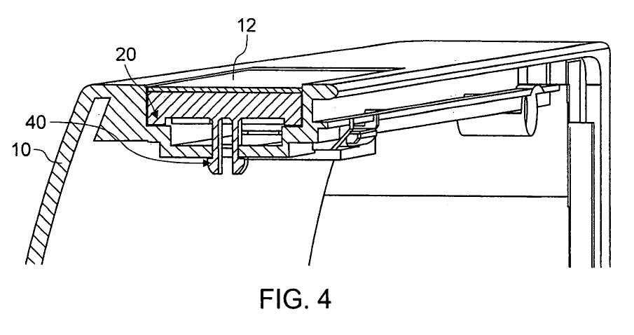

In order to fix the prefabricated control apparatus 12 in the control panel 10, a third adhesive layer 30 may be provided on the side of the control apparatus 12 facing away from the user (see FIG. 2). Alternatively or additionally, the mount element 20 may be formed with at least one latching apparatus 40, through the use of which the control apparatus 12 can be latched into corresponding latching recesses in the control panel 10, as is illustrated in FIG. 4.

As is illustrated in FIGS. 1 and 2, the control apparatus 12 also has a display area 16, in addition to the two input areas 14, in each of which a piezo-film 24 is disposed in order to form the plurality of pushbutton switches. A display element 32 in the form of a display with a seven-segment display is disposed in this display area 16, on the side of the mount element 20 facing away from the user. A printed display cover 34 composed of plastic (for example PMMA) is adhesively bonded to the mount element 20 on the side of the mount element 20 facing the user. The display element 32 may optionally also have only individual light-emitting diodes.

In the exemplary embodiment, the control apparatus 12 contains two input areas 14 with pushbutton switches, and a display area 16, although the present invention is not restricted only to this embodiment. For example, the control apparatus 12 may also contain only one input area 14 or more than two input areas 14, and a plurality of input areas 14 can also optionally be disposed alongside one another and/or one behind the other. It is also possible to dispense with the display area 16 or to provide two or more display areas 16 in the control apparatus 12. The number of pushbutton switches in an input area 14 and/or the number of sensor fields 23 on a piezo-film 24 are/is also not specifically restricted. Furthermore, each sensor field 23 on the piezo-film 24 need not necessarily have an associated pushbutton switch such that, for example, the same piezo-films 24 can be used in each case for a plurality of types and models of one domestic appliance with different input areas 14.

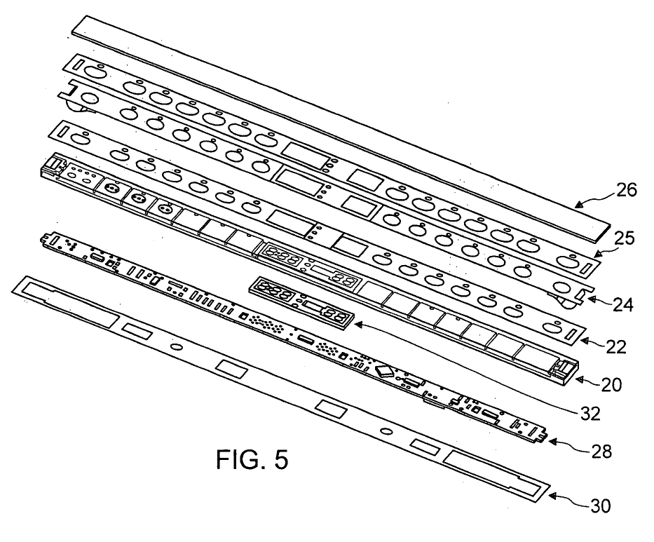

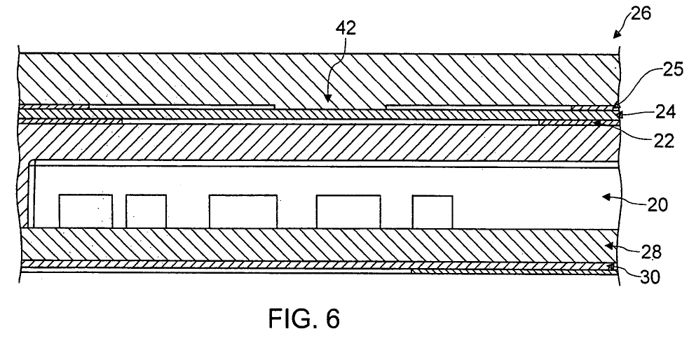

A control apparatus 12 according to a second exemplary embodiment will now be explained with reference to FIGS. 5 and 6. In this case, identical and/or corresponding components are in each case annotated with the same reference numerals as in the first exemplary embodiment.

Analogously to the first exemplary embodiment as described above, the construction of the control apparatus 12 according to the second exemplary embodiment likewise includes a mount element 20, a piezo-film 24 for the two input areas 14, a cover layer 26, a printed circuit board 28 which is inserted into the mount element 20, and a display element 32. A third adhesive layer 30 is provided as an attachment element for the control apparatus 12 in the control panel 10, and a first adhesive layer 22 is provided for a soft connection over an area between the two components, in order to connect the piezo-film 24 to the mount element 20.

The second exemplary embodiment shown in FIGS. 5 and 6 differs from the first exemplary embodiment as described above in that the second adhesive layer 25 does not form a stiff and inflexible connection over an area between the cover layer 26 and the piezo-film 24, but a soft and flexible connection over an area. This makes it possible in an advantageous manner to compensate for or at least considerably reduce different thermal expansions of the cover layer 26 and of the piezo-film 24, which are caused by their different materials, in such a way that no temperature-dependent stresses and deformation are created between the two components.

The flexibility of the second adhesive layer 25, however, reduces the transmission of the short operating movement distances from the cover layer 26 to the piezo-film 24, and is therefore inconsistent with the actual switching function of the pushbutton switches. For this reason, a force transmission element 42 is disposed in each case between the piezo-film 24 and the cover layer 26 in the area of a sensor field 23, is placed in a corresponding cutout in the second adhesive layer 25, and transmits the pressure forces from the cover layer 26, which acts as an operating surface, to the pressure-sensitive piezo-film 24. Despite the soft connection between the cover layer 26 and the piezo-film 24, the force transmission element 42 produces an inflexible connection which is required for correct operation of the pushbutton switches in the control apparatus 12. By way of example, the force transmission element 42 may be in the form of a plunger, stud or the like which is connected (by pressing or printing, adhesion, spraying or injecting, etc.) to the cover layer 26.

The other features and advantages are the same as those of the first exemplary embodiment as described above, and they will not be described again.

1. A control apparatus with at least one pushbutton switch, the control apparatus comprising:
a mount element;
a piezo-film having at least one sensor field corresponding to the at least one pushbutton switch;
a first adhesive layer connecting said piezo-film to said mount element;
a cover layer facing a user side;
a second adhesive layer connecting said cover layer to said piezo-film; and
at least one attachment element for attachment of the control apparatus to a control panel.

2. The control apparatus according to claim 1, wherein:
said mount element has a side facing away from said piezo-film, said side has a cutout formed therein; and
a printed circuit board is inserted into said cutout in said mount element.

3. The control apparatus according to claim 2, wherein said printed circuit board is held substantially completely in said cutout in said mount element.

4. The control apparatus according to claim 1, wherein:
said second adhesive layer between said piezo-film and said cover layer is soft; and
a force transmission element is disposed within an area cut out from said second adhesive layer between said piezo-film and said cover layer in vicinity of said at least one sensor field.

5. The control apparatus according to claim 4, wherein said force transmission element is a plunger connected to said cover layer.

6. The control apparatus according to claim 1, wherein said at least one attachment element contains a third adhesive layer.

7. The control apparatus according to claim 1, wherein said at least one attachment element contains a latching apparatus.

8. The control apparatus according to claim 1, which further comprises at least one display element integrated in said mount element.

9. An electronic domestic appliance, comprising:
a control panel; and
a control apparatus according to claim 1 inserted into said control panel.
